(19) United States
(12) Patent Application Publication
(10) Pub. No.: US 2026/0299044 A1
(43) Pub. Date: Oct. 1, 2026

(54) Battery Diagnosis Apparatus and Operating Method Thereof

(71) Applicant: LG ENERGY SOLUTION LTD., Seoul (KR)

(72) Inventors: Jin Woo Jang, Daejeon (KR); Ki Hoon Kim, Daejeon (KR); Jin Won Jung, Daejeon (KR)

(73) Assignee: LG ENERGY SOLUTION LTD., Seoul (KR)

(21) Appl. No.: 19/484,206

(22) PCT Filed: Oct. 30, 2023
(86) PCT No.: PCT/KR2023/017024

§ 371 Date: Nov. 13, 2025

(30) Foreign Application Priority Data
May 17, 2023 (KR) 10-2023-0063907

(51) Int. Cl. G01R 31/392; G01R 19/00; G01R 19/12; G01R 19/165; G01R 31/3842; G01R 31/396

(52) U.S. Cl. CPC G01R 31/392; G01R 19/003; G01R 19/12; G01R 19/16542; G01R 31/3842; G01R 31/396

(57) ABSTRACT

Aspects of the disclosure are directed to diagnosing abnormalities in individual battery cells of a battery pack based on a moving average and a standard deviation of the battery cells, thereby improving accuracy and efficiency of diagnosis.

### CROSS-REFERENCE TO RELATED APPLICATION

This application is a national phase entry under 35 U.S.C. § 371 of International Application No. PCT/KR2023/017024, filed on Oct. 30, 2023, which claims priority to Korean Patent Application No. 10-2023-0063907, filed on May 17, 2023, all of which is incorporated herein by reference.

### BACKGROUND

Secondary batteries are chargeable/dischargeable batteries and may include nickel (Ni)/cadmium (Cd) batteries, Ni/metal hydride (MH) batteries, and lithium-ion batteries. Among the secondary batteries, a lithium-ion battery has a higher energy density than the Ni/Cd batteries, Ni/MH batteries, etc. Moreover, the lithium-ion battery may be manufactured to be small and lightweight, such that the lithium-ion battery can be used as a power source of mobile devices. In addition, the lithium-ion battery is attracting attention as a next-generation energy storage medium for use as a power source of electric vehicles.

When a battery defect, e.g., short-circuit, negative electrode exposure, lithium precipitation, occurs in a battery cell included in a battery pack, there is a risk of fire. Therefore, detection of the defective battery cell and corresponding action in response to detecting the defective battery cell can reduce the risk of fire. Battery defects may be detected in battery packs based on an abnormal voltage behavior of the battery packs. However, detecting battery defects in a battery pack does not determine which battery cell of the battery pack is defective, resulting in wasted battery cells to replace the entire battery pack.

### BRIEF SUMMARY

Aspects of the disclosure are directed to diagnosing abnormalities in individual battery cells of a battery pack based on a moving average and a standard deviation of the battery cells, thereby improving accuracy and efficiency of diagnosis.

An aspect of the disclosure provides for battery diagnosis apparatus including: an information obtaining unit configured to obtain time-series data regarding a voltage of each of a plurality of battery cells; and a controller configured to: calculate a moving average and a standard deviation for a reference unit from the time-series data of each battery cell; and diagnose whether each battery cell is abnormal based on the moving average and the standard deviation.

In some examples, the controller may be further configured to: normalize a voltage value at a current point in time for each battery cell with a moving average and a standard deviation at a previous point in time; and calculate an error rate based on the normalized voltage value for each battery cell.

In some examples, the controller may be further configured to calculate the error rate by applying an error function to the normalized voltage value.

In some examples, the controller may be further configured to determine that a battery cell is defective based on an absolute value of the error rate exceeding a first value.

In some examples, the first value may be set to 0.65.

In some examples, the controller may be further configured to mask the error rate with 0 for a period of the time-series data in which a change rate of current is greater than a threshold degree.

In some examples, the controller may be further configured to: calculate a deviation of the error rate of each battery cell; and determine that a battery cell is defective based on an absolute value of the deviation exceeding a second value.

In some examples, the second value may be set to 0.25.

Another aspect of the disclosure provides for a battery diagnosis method including: obtaining time-series data regarding a voltage of each of a plurality of battery cells; calculating a moving average and a standard deviation for a reference unit from the time-series data of each battery cell; and diagnosing whether each battery cell is abnormal based on the moving average and the standard deviation.

In some examples, the diagnosing of whether each battery cell is abnormal may further include: normalizing a voltage value at a current point in time for each battery cell with a moving average and a standard deviation at a previous point in time; and calculating an error rate based on the normalized voltage value for each battery cell.

In some examples, the diagnosing of whether each battery cell is abnormal may further include determining that a battery cell is defective based on having an absolute value of the error rate exceeding a first value.

In some examples, the calculating of the error rate may further include calculating the error rate by applying an error function to the normalized voltage value.

In some examples, the calculating of the error rate may further include masking the error rate with 0 for a period of the time-series data in which a change rate of current is greater than a threshold degree.

In some examples, the diagnosing of whether each battery cell is abnormal may further include: calculating a deviation of the error rate of each battery cell; and determining that a battery cell is defective based on an absolute value of the deviation exceeding a second value.

### BRIEF DESCRIPTION OF THE DRAWINGS

FIG. 1 is a block diagram of a battery pack according to aspects of the disclosure.

FIG. 2 is a block diagram of a battery diagnosis apparatus according to aspects of the disclosure.

FIG. 3A is a graph showing an example of time-series data regarding a voltage of each of a plurality of battery cells according to aspects of the disclosure.

FIG. 3B is a graph showing an example of an error rate calculated for a battery cell according to aspects of the disclosure.

FIG. 3C is a graph showing enlarged aspects of the example error rate calculated for a battery cell according to aspects of the disclosure.

FIG. 3D is a graph showing enlarged aspects of the example error rate calculated for a battery cell according to aspects of the disclosure.

FIG. 4 is a graph showing an example of an error rate deviation of battery cells according to aspects of the disclosure.

FIG. 5 is a flowchart of a battery diagnosis method according to aspects of the disclosure.

FIG. 6 is a flowchart of further detail of the battery diagnosis method according to aspects of the disclosure.

FIG. 7 is a block diagram of a computing system according to aspects of the disclosure.

### DETAILED DESCRIPTION

The disclosure may be modified in various forms and have various examples, and specific examples thereof are shown by way of drawings and description below. It should be understood, however, that there is no intent to limit the disclosure to the specific examples, but on the contrary, the disclosure is to cover all modifications, equivalents, and alternatives falling within the spirit and technical scope of the disclosure. Like reference numerals refer to like elements throughout the description of the figures.

It will be understood that, although the terms such as first, second, A, B, and the like may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes combinations of a plurality of associated listed items or any of the plurality of associated listed items.

It will be understood that when an element is referred to as being “connected” to another element, it can be directly connected to the other element or an intervening element may be present.

The terms used herein are for the purpose of describing specific examples only and are not intended to limit the disclosure. As used herein, the singular forms “a”, “an” and “the” are intended to include the plural forms as well, unless the context clearly indicates otherwise. It will be further understood that the terms “comprises”, “comprising”, “includes”, “including” and/or “having”, when used herein, specify the presence of stated features, integers, steps, operations, constitutional elements, components and/or combinations thereof, but do not preclude the presence or addition of one or more other features, integers, steps, operations, constitutional elements, components, and/or combinations thereof.

Aspects of the disclosure may be provided in a computer program product. The computer program product may be traded as a product between a seller and a buyer. The computer program product may be distributed in the form of a machine-readable storage medium, e.g., compact disc read only memory (CD-ROM)), or be distributed, e.g., downloaded or uploaded, online via an application store, or be distributed between two user devices directly. If distributed online, at least part of the computer program product may be temporarily generated or at least temporarily stored in the machine-readable storage medium, such as memory of the manufacturer's server, a server of the application store, or a relay server.

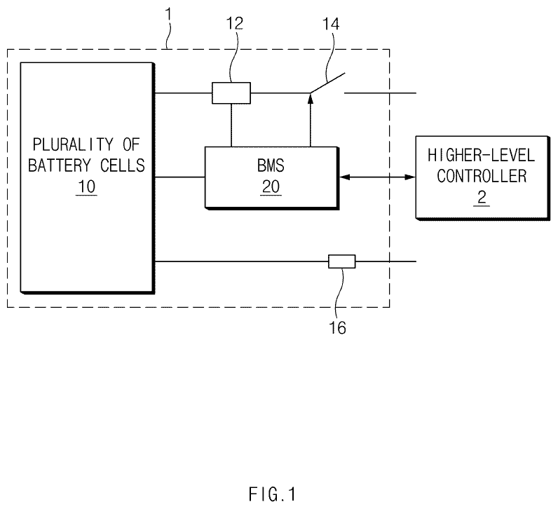

FIG. 1 is a block diagram showing a configuration of a battery pack 1 and a higher-level controller 2. The battery pack 1 may include a plurality of battery cells 10, a sensor 12, a switching unit 14, and a battery management system 20.

The plurality of battery cells 10 may include one or more chargeable/dischargeable battery cells. The switching unit 14 may be serially connected to positive (+) terminal sides or negative (−) terminal sides of the plurality of battery cells 10 to control a charging/discharging current flow of the plurality of battery cells 10. For example, the switching unit 14 may be at least one relay and/or magnetic contactor to be used according to specifications of the battery pack 1.

The battery management system 20 may control and manage the plurality of battery cells 10 to prevent over-charging and over-discharging by monitoring parameter values of the battery pack 1, e.g., voltage, current, and/or temperature, from the sensor 12. The battery management system 20 may be an interface for receiving measurement values of the parameter values, may include a plurality of terminals and a circuit connected thereto to process input values. The battery management system 20 may control the switching unit 14 to be on or off, and may be connected to the plurality of battery cells 10 to monitor the state of each battery cell 10.

The higher-level controller 2 may transmit a control signal regarding the plurality of battery cells 10 to the battery management system 20. Thus, the battery management system 20 may also be controlled in terms of an operation thereof based on a signal applied from the higher-level controller 2.

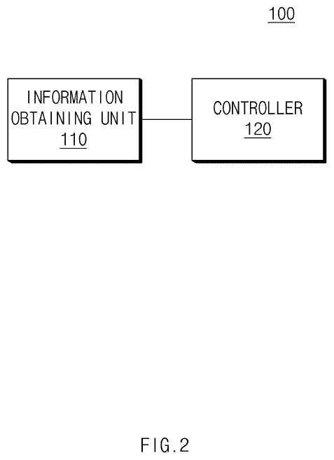

FIG. 2 is a block diagram of a battery diagnosis apparatus 100. The battery diagnosis apparatus 100 may be included as part of a battery management system 20, such as the battery management system 20 as depicted in FIG. 1. Alternatively, or additionally, the battery diagnosis apparatus 100 may be separate from the battery management system and may be included as part of the battery pack or a device separate from the battery pack, e.g., a server, a cloud, a charger, and/or a charger/discharger.

The battery diagnosis apparatus 100 may process time-series data regarding a voltage of each of a plurality of battery cells included in a battery pack to diagnose voltage abnormality in an individual battery cell. The battery diagnosis apparatus 100 may diagnose whether a battery cell is abnormal by determining if there is an abnormal voltage behavior for each battery cell.

The battery diagnosis apparatus 100 may include an information obtaining unit 110 and a controller 120. The information obtaining unit 110 may obtain time-series data regarding a voltage of each of the plurality of battery cells. For example, the information obtaining unit 110 may obtain the time-series data by obtaining a voltage value at time intervals determined for each battery cell. For example, the information obtaining unit 110 may obtain time-series data (v₁, v₂, vₘ) regarding m voltage values obtained at m points in time for each battery cell. The information obtaining unit 110 may further obtain cell-related data, such as current and/or temperature, in addition to the voltage of each battery cell.

The controller 120 may calculate a moving average and a standard deviation for a reference unit from the time-series data of each battery cell. The moving average may refer to an average calculated while moving a subset having a specific size in the time-series data, where the size of the subset may refer to the number of pieces of data belonging to the subset. For example, when the size of the subset is 5, the controller 120 may calculate the moving average for five adjacent pieces of data in time-series data of each battery cell. A moving average calculated at a point in time t may refer to an average value from voltage data at a point in time (t−4) to voltage data (vₜ₋₄~vₜ) at the point in time t.

The reference unit may be a unit indicating the size of the subset for calculating the moving average in the time-series data. For example, when the size of the subset used for moving average calculation is 5, the reference unit may be 5. In another example, when the size of the subset is 5 and the time-series data is obtained at a time interval of 1 second, then the reference unit may be 5 seconds. Likewise, the controller 120 may calculate the standard deviation for the reference unit.

For example, when time-series data for a voltage of a specific cell obtained by the information obtaining unit 110 is (v₁, v₂, . . . , vₘ), then the controller 120 may calculate time-series data for the moving average and time-series data for the standard deviation therefrom. For the reference unit of 5, the calculated moving average and standard deviation may be expressed as (mean₅, mean₆, . . . ,meanₘ) and (std₅, std₆, . . . ,stdₘ) respectively.

In this example, the moving average and the standard deviation may satisfy the following equations.

$${mean}_{t} = {mean}_{t - 1} + \frac{{v}_{t} - {mean}_{t - 1}}{n} \qquad [ Equation 1 ]$$

$${std}_{t} = s t {d}_{t - 1} + \frac{{( {v}_{t} - {mean}_{t - 1} )}^{2}}{n} - \frac{s t {d}_{t - 1}}{n - 1} \qquad [ Equation 2 ]$$

meanₜ and stdₜ may refer to the moving average and the standard deviation at the point in time t, respectively, vₜ may mean a time-series data term of a voltage at the point in time t, and n may mean a reference unit. Thus, the controller 120 may calculate the moving average and the standard deviation to examine distribution, change, and/or behavior of the moving average and the standard deviation. For example, the controller 120 may identify a trend of voltage distribution of each battery cell based on the moving average and the standard deviation.

The controller 120 may diagnose whether each battery cell is abnormal based on the moving average and the standard deviation. For example, when a change of a moving average or a standard deviation of a specific cell at a certain point in time exceeds a threshold value, the controller 120 may determine that the cell is defective and/or determine that more detailed analysis is required. Alternatively, or additionally, the controller 120 may calculate a parameter, e.g., an error rate, for cell diagnosis from the moving average and the standard deviation and diagnose whether the cell is abnormal based on the calculated parameter.

The controller 120 may normalize a voltage value at a current point in time for each battery cell with a moving average and a standard deviation at a previous point in time. The controller 120 may normalize a voltage value of each term of time-series data with the moving average and the standard deviation calculated at the previous point in time, thereby calculating the normalized voltage value. For example, the normalized voltage value may be expressed as

$${norm}_{t} = \frac{{v}_{t} - {mean}_{t - 1}}{s t {d}_{t - 1}} .$$

The controller 120 may normalize each term of time-series data, thereby identifying distribution of a voltage behavior by applying characteristics of a voltage behavior, e.g., a moving average and a standard deviation, at the previous point in time to data of each term.

The controller 120 may calculate an error rate based on the normalized voltage value for each battery cell. The controller 120 may calculate the error rate based on the normalized voltage value, thereby quantifying and identifying the extent to which the voltage behavior of the cell deviates from normal distribution. The controller 120 may normalize a voltage value of each term and calculate an error rate, thereby more clearly identifying whether the cell is abnormal and improving the accuracy of diagnosis.

The controller 120 may calculate an error rate by applying an error function to the normalized voltage value. For example, the error function may be expressed as

$$erf ( x ) = \frac{2}{\sqrt{π}} {\int }_{0}^{x} {e}^{- {t}^{2}} dt ,$$

and the error rate may be expressed as diagₜ=erf(normₜ). In this example, the error rate may have a range of [−1, 1], in which the closer the error rate is to 0, the closer the error rate is to the existing distribution and the closer the error rate is −1 or 1, the farther the error rate is from the existing distribution.

The controller 120 may determine that a battery cell is defective based on having an absolute value of an error rate that exceeds a first value. The controller 120 may determine that the cell is defective by determining that abnormality occurs in the cell, because the greater absolute value of the error rate may mean that the voltage behavior of the cell deviates significantly from the existing distribution. For example, the controller 120 may determine that a specific battery cell is defective when an absolute value of an error rate exceeds the first value at any one point in time. In another example, the controller 120 may determine that a battery cell is defective when the absolute value of the error rate of the specific cell exceeds the first value at least a preset number of times.

The first value may be predetermined, such as from statistics and/or experiments that determine a value for distinguishing a normal behavior of a battery cell voltage from an abnormal behavior of the battery cell voltage. For example, the first value may be set to be greater than a maximum error rate that may generally occur in the normal behavior of the battery cell voltage. For example, the first value may be set to 0.65.

As such, the controller 120 may process the voltage behavior of each battery cell, thereby separately diagnosing whether each cell is abnormal. The controller 120 may separately analyze each battery cell to diagnose whether that battery cell is abnormal as well as analyze a relativity of each battery cell in the battery pack to diagnose whether any battery cell is abnormal.

The controller 120 may calculate an error rate deviation of each battery cell. For example, the controller 120 may calculate an average of error rates of each battery cell at the same point in time and calculate an error rate deviation from a difference between the error rate of and the average of each battery cell.

The controller 120 may determine that a battery cell is defective based on having an absolute value of an error rate deviation that exceeds a second value. When a deviation of a specific battery cell is large in the same environment, the battery cell has a behavior different from other battery cells, such that the controller 120 may determine that the battery cell is defective.

The second value may be predetermined, such as from statistics and/or experiments that determine a value for distinguishing a normal behavior of a battery cell voltage from an abnormal behavior of the battery cell voltage. For example, the second value may be set to be greater than a relative deviation that may generally occur in the normal behavior of the battery cell voltage. For example, the second value may be set to 0.25.

As such, the controller 120 may diagnose whether each cell is abnormal, by relatively analyzing battery cells in the battery pack 1. For example, when the voltage behaviors of the battery cells significantly deviate from the previous behavior distribution, but all the cells have the same voltage behavior, then more than one battery cell may be defective. The controller 120 may determine that the battery pack 1 is defective or needs precise diagnosis, when battery cells determined as defective exceed a preset number or a preset rate. For example, when those determined as defective exceed a preset rate of total battery cells included in the battery pack 1 as a result of diagnosing each battery cell, the controller 120 may determine that the battery pack 1 is a precise diagnosis target.

When the battery cell is identified as defective as a result of diagnosis, the controller 120 may provide information about an abnormal battery cell to a user. For example, the controller 120 may provide information about a defective battery cell to a user terminal through a communication unit (not shown) and provide the information about the defective battery cell through a display provided in a vehicle, and/or a charger, as examples.

The controller 120 may mask an error rate with 0 for a period of time-series data in which a change rate of current is greater than a threshold degree. That is, the controller 120 may perform masking by replacing an error rate calculated in a period corresponding to a large current change of each battery cell with 0. The current of each battery cell may be obtained from the information obtaining unit 110. For example, when the change rate of the current of the battery cell is greater than the threshold degree at a point in time when the time-series is obtained, then the controller 120 may mask an error rate calculated at that point in time with 0.

For example, in a charging/discharging period of the battery cell, the voltage change of the battery cell may be large due to the sharp change of the charging/discharging current. However, the large change of the battery cell voltage occurring in this case may corresponding to the normal behavior rather than the abnormal behavior, and thus may need to be distinguished from the abnormal behavior corresponding to the actual defect. Thus, the controller 120 may mask the error rate with 0 in a period where the change rate of the current of the battery cell is greater than the threshold degree, so as to prevent the battery cell from being determined as defective even when the voltage behavior of the battery cell is normal. To this end, the battery diagnosis apparatus 100 may prevent the normal behavior from being misdiagnosed as the abnormal behavior in a charging/discharging period.

The controller 120 may perform diagnosis of a battery cell in a period where the change rate of the current of the battery cell is less than or equal to a predetermined level. For example, the controller 120 may perform diagnosis of the battery cell in a period of ΔI<2 mV, and for example, the controller 120 may perform a diagnosis procedure in an idle period of the battery pack 1. The controller 120 may perform a diagnosis procedure in a period where a voltage behavior is stable due to a low change rate of the current, such as in the idle period, to prevent a sharp voltage change in some periods, such as occurring according to a charging/discharging pattern, from being misdiagnosed as the abnormal behavior even when the voltage behavior of the battery cell is normal.

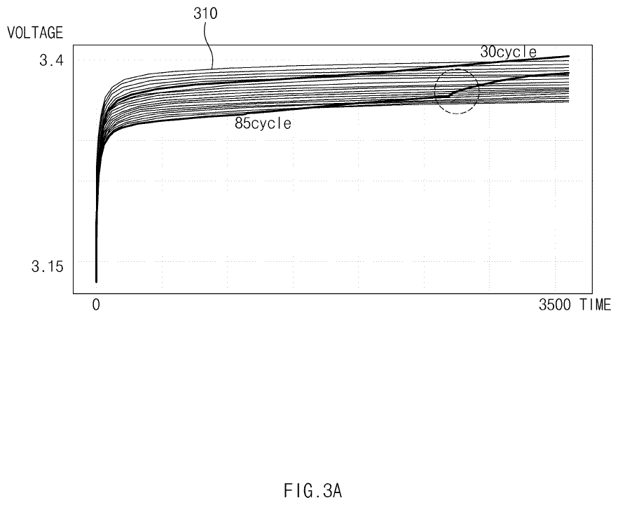

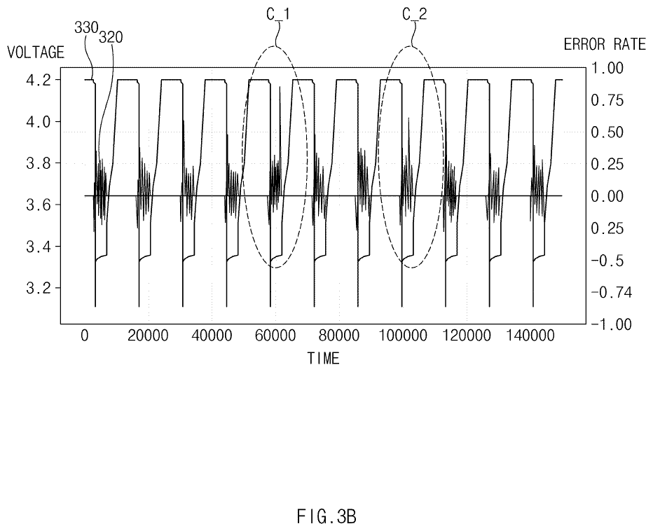

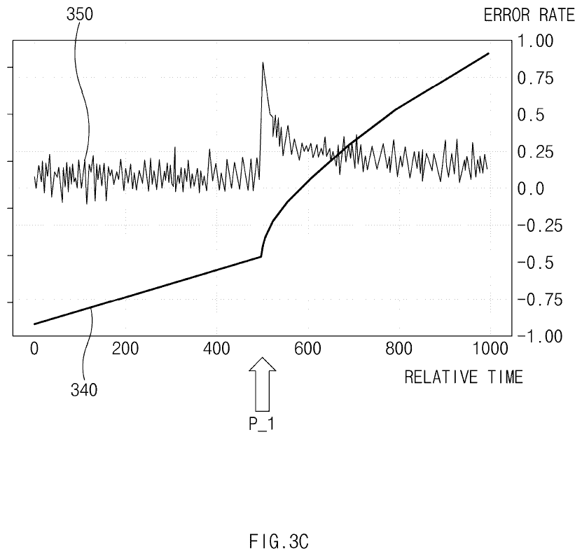

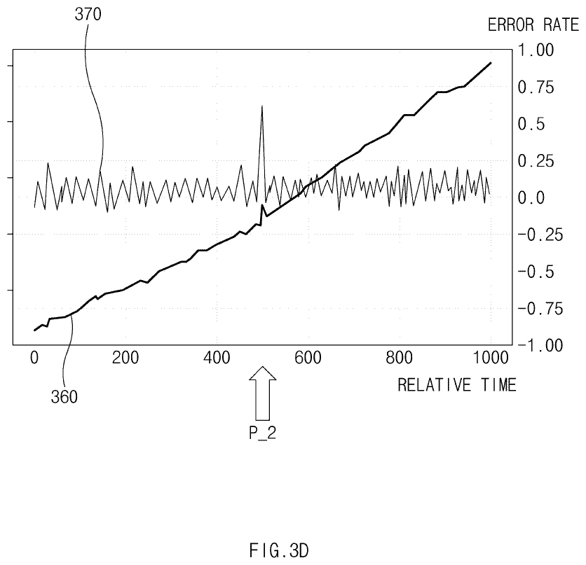

FIG. 3A shows an example of time-series data regarding a voltage of each of a plurality of battery cells. A graph 310 of time-series data regarding a voltage of each battery cell is shown. In the graph 310, each line may indicate a graph for time-series data of each battery cell. The battery diagnosis apparatus 100 may aim to detect abnormality of the voltage behavior occurring in a specific battery cell, for example, as in a part indicated by the circle show in FIG. 3A.

FIGS. 3B to 3D show an example of an error rate calculated for a battery cell. More specifically, FIGS. 3C and 3D enlarge and express periods C_1 and C_2 of FIG. 3B, respectively.

Referring to FIG. 3B, a graph 320 regarding an error rate of a specific battery cell and a graph 330 regarding a voltage are shown. In FIG. 3B, an x-axis example indicates a time, a left y-axis example indicates a voltage, and a right y-axis example indicates an error rate. The battery diagnosis apparatus 100 may determine abnormality of a battery cell based on an absolute value of an error rate calculated for the battery cell. For example, the battery diagnosis apparatus 100 may detect a point at which the absolute value of the error rate of the battery cell exceeds the first value.

The controller 120 may mask an error rate with 0 in a period in which the change rate of the current of the battery cell is greater than the threshold degree. It may be seen from the graph 330 regarding the voltage in FIG. 3B that in the charging/discharging period in which the voltage changes rapidly (the voltage behavior is normal but the voltage change rate is also high as the current change rate is high), the error rate is processed as 0 in the graph 320 regarding the error rate.

FIGS. 3C and 3D enlarge and express periods C_1 and C_2 of FIG. 3B, respectively. A graph 350 regarding the error rate of FIG. 3C and a graph 370 regarding the error rate of FIG. 3D are parts of the graph 320 regarding the error rate of FIG. 3B. A graph 340 regarding the voltage of FIG. 3C and a graph 360 regarding the error rate of FIG. 3D are parts of the graph 330 regarding the error rate of FIG. 3B. In FIGS. 3C and 3D, an x-axis indicates a relative time with respect to 0 as a start point of each of the periods C_1 and C_2. The battery diagnosis apparatus 100 may detect a point P_1 of FIG. 3C and a point P_2 of FIG. 3D at which the absolute value of the error rate is greater than or equal to the threshold value. In this case, the threshold value may be set between, for example, 0.4 and 0.65.

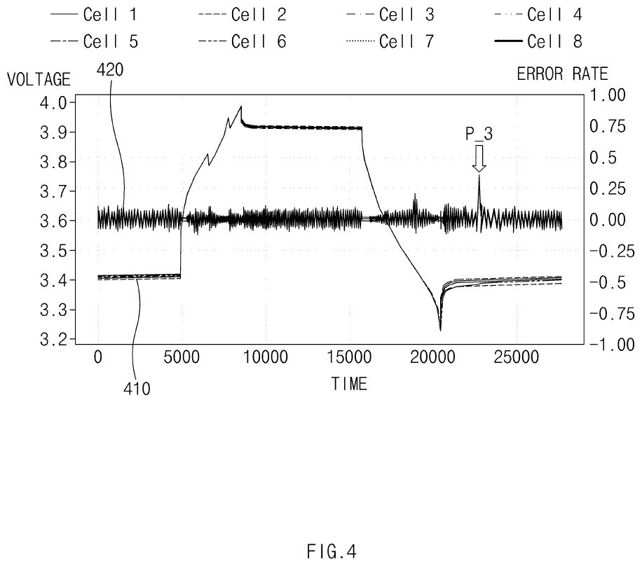

FIG. 4 shows an example of an error rate deviation of battery cells. A graph 410 regarding a charging/discharging voltage for each battery cell and a graph 420 regarding an error rate deviation of each battery cell are shown. While 8 battery cells are illustrated in FIG. 4, the number of battery cells is not limited thereto.

As the voltage of each battery cell included in the battery pack 1 changes according to the same charging/discharging pattern, the controller 120 may detect a specific cell having a large error rate deviation from the graph 420 regarding the error rate deviation during this process. For example, the battery diagnosis apparatus 100 may detect a point P_3 at which the absolute value of the error rate exceeds the second value. In this case, the second value may be set between, for example, 0.24 and 0.28.

The controller 120 may mask the error rate with 0 in a period in which the change rate of the current of the battery cell is greater than the threshold degree, such that as the error rate of every cell is masked with 0 in that period, the error rate deviation is 0.

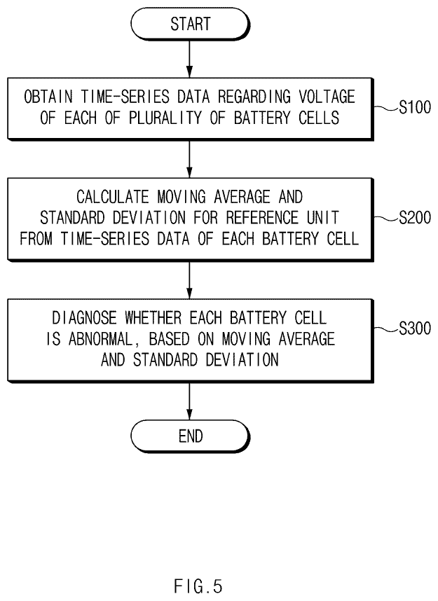

FIG. 5 is a flowchart of a battery diagnosis method. The operations shown in FIG. 5 may be performed by a battery diagnosis apparatus, such as the battery diagnosis apparatus 100 of FIG. 2.

In operation S100, the information obtaining unit 110 obtains time-series data regarding a voltage of each of the plurality of battery cells.

In operation S200, the controller 120 calculates the moving average and the standard deviation for a reference unit from the time-series data of each battery cell.

In operation S300, the controller 120 diagnoses whether each battery cell is abnormal based on the moving average and the standard deviation. For example, the controller 120 may determine the battery cell as defective when the moving average and/or standard deviation is greater than a threshold value. In another example, the controller 120 may calculate a parameter, e.g., an error rate, for cell diagnosis from the moving average and the standard deviation and diagnose whether the cell is abnormal based on the calculated parameter.

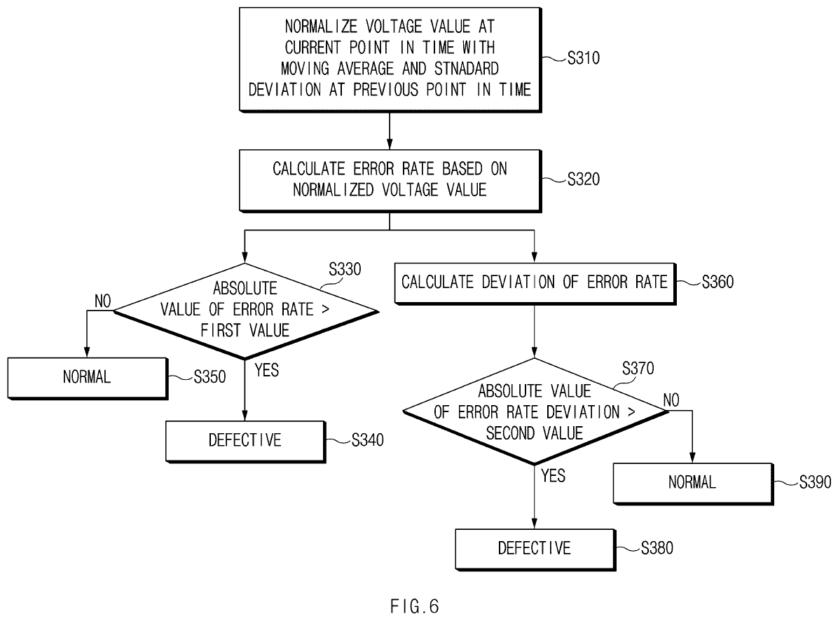

FIG. 6 is a flowchart of further detail of the battery diagnosis method. The operations shown in FIG. 6 may be performed by a battery diagnosis apparatus, such as the battery diagnosis apparatus 100 of FIG. 2.

In operation S310, the controller 120 may normalize a voltage value at a current point in time for each battery cell with a moving average and a standard deviation at a previous point in time. For example, when the current point in time is t, the controller 120 may normalize the voltage vₜ of the battery cell with the moving average meanₜ₋₁ and the standard deviation stdₜ₋₁ at the point (t−1) in time.

In operation S320, the controller 120 may calculate an error rate based on the normalized voltage value for each battery cell. For example, the controller 120 may calculate the error rate by applying an error function to the normalized voltage value.

In operation S330, the controller 120 may determine whether the absolute value of the error rate for each battery cell exceeds the first value.

In operation S340, when the absolute value of the error rate exceeds the first value, the controller 120 may determine that the corresponding battery cell is defective. In operation S350, when the absolute value of the error rate is less than or equal to the first value, the controller 120 may determine that the corresponding battery cell is normal.

In operation S360, the controller 120 may calculate an error rate deviation of each battery cell.

In operation S370, the controller 120 may determine whether the absolute value of the error rate deviation for each battery cell exceeds the second value.

In operation S380, when the absolute value of the error rate deviation exceeds the second value, the controller 120 may determine that the corresponding battery cell is defective. In operation S390, when the absolute value of the error rate is less than or equal to the second value, the controller 120 may determine that the corresponding battery cell is normal.

The controller 120 may selectively, simultaneously, or sequentially perform operations S330 and S360.

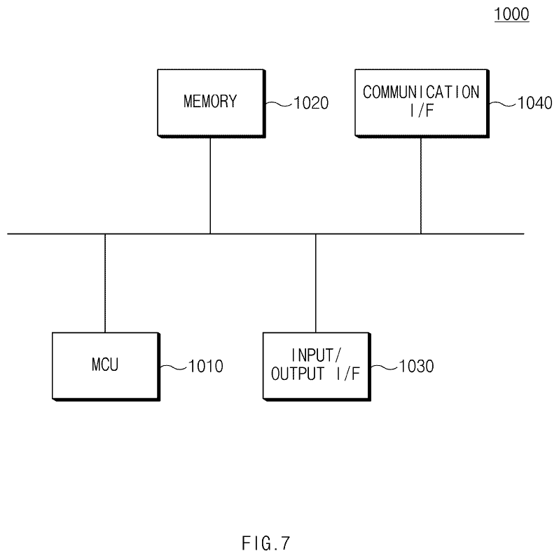

FIG. 7 is a block diagram showing a hardware configuration of a computing system 1000 for performing an operating method of a battery diagnosis apparatus. The computing system 1000 may include an MCU 1010, a memory 1020, an input/output I/F 1030, and a communication I/F 1040.

The MCU 1010 may be a processor that executes various programs, e.g., a battery cell diagnosis program, stored in the memory 1020, processes various information including voltages of the battery cell through these programs, and executes the above-described functions of the controller 120 included in the battery diagnosis apparatus shown in FIG. 2.

The memory 1020 may store various programs such as a battery cell diagnosis program. Moreover, the memory 1020 may store various information such as voltages of the battery cell.

The memory 1020 may be one or more memories. The memory 1020 may be volatile memory or non-volatile memory. For the memory 1020 as the volatile memory, random access memory (RAM), dynamic RAM (DRAM), static RAM (SRAM), etc., may be used, as examples. For the memory 1020 as the nonvolatile memory, read only memory (ROM), programmable ROM (PROM), electrically alterable ROM (EAROM), erasable PROM (EPROM), electrically erasable PROM (EEPROM), flash memory, etc., may be used, as examples. The memory 1020 may be a transitory or non-transitory computer readable medium. As such, a computer program according to aspects of the disclosure may be recorded in the memory 1020 and processed by the MCU 1010, thus being implemented as a module that performs operations shown in FIGS. 5-6.

The input/output I/F 1030 may provide an interface for transmitting and receiving data by connecting an input device (not shown) such as a keyboard, a mouse, and/or a touch panel, and an output device (not shown), such as a display, to the MCU 1010.

The communication I/F 1040 may be configured to transmit and receive various data to and from a server and may be capable of supporting wired or wireless communication. For example, the battery diagnosis apparatus may transmit and receive various information including the voltages of the battery cell from an external server separately provided through the communication I/F 1040.

Unless otherwise stated, the foregoing alternative examples are not mutually exclusive but may be implemented in various combinations to achieve unique advantages. As these and other variations and combinations of the features discussed above can be utilized without departing from the subject matter defined by the claims, the foregoing description of the examples should be taken by way of illustration rather than by way of limitation of the subject matter defined by the claims. In addition, the provision of the examples described herein, as well as clauses phrased as “such as,” “including” and the like, should not be interpreted as limiting the subject matter of the claims to the specific examples; rather, the examples are intended to illustrate only one of many possible implementations. Further, the same reference numbers in different drawings can identify the same or similar elements.

1.-14. (canceled)

15. A battery diagnosis apparatus comprising one or more processors configured to:
obtain time-series data regarding a voltage of each of a plurality of battery cells;
calculate a moving average and a standard deviation for a reference unit from the time-series data of each battery cell, and
diagnose whether each battery cell is abnormal based on the moving average and the standard deviation.

16. The battery diagnosis apparatus of claim 15, wherein the one or more processors are further configured to:
normalize a voltage value at a current point in time for each battery cell with a moving average and a standard deviation at a previous point in time; and
calculate an error rate based on the normalized voltage value for each battery cell.

17. The battery diagnosis apparatus of claim 16, wherein the one or more processors are further configured to calculate the error rate by applying an error function to the normalized voltage value.

18. The battery diagnosis apparatus of claim 16, wherein the one or more processors are further configured to determine a battery cell is defective based on having an absolute value of the error rate exceeding a first value.

19. The battery diagnosis apparatus of claim 18, wherein the first value is set to 0.65.

20. The battery diagnosis apparatus of claim 16, wherein the one or more processors are further configured to mask the error rate with 0 for a period of the time-series data in which a change rate of current is greater than a threshold degree.

21. The battery diagnosis apparatus of claim 16, wherein the one or more processors are further configured to calculate a deviation of the error rate of each battery cell.

22. The battery diagnosis apparatus of claim 21, wherein the one or more processors are further configured to determine a battery cell is defective based on having an absolute value of the deviation exceeding a second value.

23. The battery diagnosis apparatus of claim 22, wherein the second value is set to 0.25.

24. A battery diagnosis method comprising:
obtaining time-series data regarding a voltage of each of a plurality of battery cells;
calculating a moving average and a standard deviation for a reference unit from the time-series data of each battery cell; and
diagnosing whether each battery cell is abnormal based on the moving average and the standard deviation.

25. The battery diagnosis method of claim 24, wherein the diagnosing of whether each battery cell is abnormal further comprises:
normalizing a voltage value at a current point in time for each battery cell with a moving average and a standard deviation at a previous point in time; and
calculating an error rate based on the normalized voltage value for each battery cell.

26. The battery diagnosis method of claim 25, wherein the calculating of the error rate further comprises applying an error function to the normalized voltage value.

27. The battery diagnosis method of claim 25, wherein the diagnosing of whether each battery cell is abnormal further comprises determining a battery cell is defective based on having an absolute value of the error rate exceeding a first value.

28. The battery diagnosis method of claim 25, wherein the calculating of the error rate further comprises masking the error rate with 0 for a period of the time-series data in which a change rate of current is greater than a threshold degree.

29. The battery diagnosis method of claim 25, wherein the diagnosing of whether each battery cell is abnormal further comprises calculating a deviation of the error rate of each battery cell.

30. The battery diagnosis method of claim 29, wherein the diagnosing of whether each battery cell is abnormal further comprises determining a battery cell is defective based on having an absolute value of the deviation exceeding a second value.

31. A non-transitory computer readable medium for storing instructions that, when executed by one or more processors, cause the one or more processors to perform a battery diagnosis method, the method comprising:
obtaining time-series data regarding a voltage of each of a plurality of battery cells;
calculating a moving average and a standard deviation for a reference unit from the time-series data of each battery cell; and
diagnosing whether each battery cell is abnormal based on the moving average and the standard deviation.

32. The non-transitory computer readable medium of claim 31, wherein the diagnosing of whether each battery cell is abnormal further comprises:
normalizing a voltage value at a current point in time for each battery cell with a moving average and a standard deviation at a previous point in time; and
calculating an error rate based on the normalized voltage value for each battery cell.

33. The non-transitory computer readable medium of claim 32, wherein the diagnosing of whether each battery cell is abnormal further comprises determining a battery cell is defective based on having an absolute value of the error rate exceeding a first value.

34. The non-transitory computer readable medium of claim 32, wherein the diagnosing of whether each battery cell is abnormal further comprises:
calculating a deviation of the error rate of each battery cell; and
determining a battery cell is defective based on having an absolute value of the deviation exceeding a second value.
